(19) United States
(12) Patent Application Publication
(10) Pub. No.: US 2008/0107826 A1
(43) Pub. Date: May 8, 2008

(54) Method and apparatus for fabricating nanostructure multi-element compound

(75) Inventors: Jyh Shin Chen, Hsinchu City (TW); Sheng-Yuan Chen, Hsin-Chu City (TW); Yi-Chiuen Hu, Baoshan Township (TW); Shao-Chang Cheng, Yonghe City (TW); Hsiao-yu Chou, Hsin-Chu City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Instrument Technology Research Center, Hsin-Chu City (TW)

(21) Appl. No.: 11/299,930

(22) Filed: Dec. 12, 2005

(30) Foreign Application Priority Data
Jan. 4, 2005 (TW) 094100194

(51) Int. Cl. C23C 14/28; C23C 16/00

(52) U.S. Cl. 427/595; 118/715

(57) ABSTRACT

A method and an apparatus for fabricating a multi-element compound nanostructure are provided. The method includes steps of providing a substrate in a chamber, providing a particle-beam having plural first particles, providing a particle source having plural second particles to fill the chamber therewith and focusing the particle-beam on the substrate and depositing the first particles with the second particles on the substrate to form the multi-element compound nanostructure. In comparison with the conventional ones, the provided method is more simplified and has a great potentiality for being applied.

### FIELD OF THE INVENTION

The present invention relates to a method and an apparatus for fabricating a nanostructure, and more particularly to a method and an apparatus for fabricating a multi-element compound nanostructure.

### BACKGROUND OF THE INVENTION

Recently, the development of the nano-technology attracts much attention and brings a great amount of demands and improvements for the relevant techniques. Techniques for fabricating and analyzing various nano structures are also highly improved accordingly. However, people still know little about the physical properties of a material with a nano-scaled structure and still keep making more and more efforts therefor, while they have known much about a material with an atomic-scaled structure as well as a general-sized material.

While the scale of the material is reduced to a level of nanometer, which is called a “nano-material” hereafter, the physical and chemical properties thereof are completely different from those of the typical bulk due to the quantum confinement effect and the improving surface effect. Therefore, the essential properties of the material, such as the melting point, the color, the optical property, the electrical property and the magnetic property, are different if the size and the shape of the material are changed, even though the composition thereof remains unchanged.

The compound semiconductor is the most important material in the optoelectronic application, which is composed of different components having different gaps so as to form a quantum well thereof. The carrier mobility and the photo efficiency of the compound semiconductor could be enhanced since the threshold current thereof is reduced by the quantum well.

The optoelectronic compound semiconductor is typically fabricated by means of the epitaxy techniques including the liquid-phase epitaxy (LPE), the molecular beam epitaxy (MBE) and the metalorganic vapor-phase epitaxy (MOVPE), which may make the fabricated compound semiconductor have different optoelectronic properties. The typical principle adopted in the epitaxy technique relates to the atom stacking. More specifically, the compound semiconductor relates to a specific structure formed by stacking several materials whose lattice constants are different on a common substrate. While forming a compound semiconductor, the problem of lattice mismatch therefor should be seriously taken into considered, and hence a “system” having different materials of similar lattice constants, such as the AlGaAs/GaAs system and the InGaAsP/InP system, is preferably applied.

Among the mentioned epitaxy techniques, MOVPE is the most typical one which has gradually replaced the prior LPE and MBE techniques. The principle adopted in MOVPE is simple, but the processing steps thereof are quite complicated. Gaseous compounds of the III-V group, so-called precursors, are needed as starting materials and fed into the reactor with the aid of a carrier gas. The carrier gas flow and the feeding period thereof are controllable for reducing the growth rate of the compound semiconductor, so as to perform a desired epitaxy growth. In general, MOVPE is suitable for mass production, but it is difficult to be improved due to the complexity thereof.

In order to enhance the performance of the optoelectronic devices and improve the fabrication of novel materials therefor, a great effort has been made in researching the quantum structure of the multi-element compound, such as the quantum dots and the quantum wires, in which the low dimensional quantum confinement structure thereof makes it possible to realize the optoelectronic device for the high speed and high performance applications. As for the optoelectronic device, there are various processes for fabricating the multi-element compound, which include the lithography and the ball-milling process in addition to the mentioned epitaxy growth. Alternatively, MBE and the vapor phase deposition which adopts the catalyst-template Stranski-Krastanov growth mode are also applicable for fabricating the multi-element compound for the optoelectronic device. However, all of the mentioned processes are extremely complicated and difficult to be performed.

In addition to the problem of complication, the mentioned processes are still disadvantageous because additional processes are always necessary therefor and the growth position of the quantum structure is unable to be precisely controlled therethrough.

In order to overcome the above drawbacks in the processes according to the prior art, the present invention provides a novel method and apparatus for fabricating a multi-element compound nanostructure. In comparison with the conventional ones, the provided method is more simplified and has a great potentiality for being applied.

### SUMMARY OF THE INVENTION

In accordance with a first aspect of the present invention, a method for fabricating a multi-element compound nanostructure is provided. The method includes steps of providing a substrate in a chamber, providing a particle-beam having plural first particles, providing a particle source having plural second particles to fill the chamber therewith and focusing the particle-beam on the substrate and depositing the first particles with the second particles on the substrate to form the multi-element compound nanostructure.

Preferably, the method further includes a step of heating the substrate.

Preferably, the substrate is heated to a growth temperature of the multi-element compound nanostructure.

Preferably, the method further includes a step of scanning the substrate for a growth position of the multi-element compound nanostructure via an electron-beam.

Preferably, the substrate is patterned via the electron-beam.

Preferably, the chamber is in vacuum.

Preferably, the method further includes a step of drawing out and accelerating the particle beam via a high voltage.

Preferably, the particle beam is a metal ion-beam.

Preferably, the metal ion-beam is one of a liquidized metal ion-beam and a vaporized metal ion-beam.

Preferably, the particle source is an atom source.

Preferably, the atom source is a vaporized atom source.

Preferably, the particle-beam is focused via one of an electromagnetic lens and an optical lens with an objective.

Preferably, the multi-element compound nanostructure is one selected from a group consisting of a quantum dot, a nano-wire, a nano-column, an array of nano-columns, a nano-spiral and a three-dimensional nano-network.

In accordance with a second aspect of the present invention, a method for fabricating a multi-element compound nanostructure is provided. The method includes steps of providing a substrate in a chamber, providing plural ion-beams, drawing out and accelerating the ion-beams via a high voltage, providing the chamber with plural atoms from a vaporized atom source, and focusing the ion-beams on the substrate to be deposited with the atoms on the substrate to form the multi-element compound nanostructure.

Preferably, the ion-beams include at least a first metal ion-beam and a second metal ion-beam.

Preferably, the method further includes a step of heating the substrate.

Preferably, the substrate is heated to a growth temperature of the multi-element compound nanostructure.

Preferably, the multi-element compound nanostructure is one selected from a group consisting of a quantum dot, a nano-wire, a nano-column, an array of nano-columns, a nano-spiral and a three-dimensional nano-network.

In accordance with a third aspect of the present invention, an apparatus for fabricating a multi-element compound nanostructure is provided. The provided apparatus includes a chamber in vacuum having a base for holding a substrate therein, a heating device in the chamber for heating the substrate, plural particle sources having at least a first and a second particle sources for providing a first and a second particle-beams respectively, an atom source for providing the chamber with plural atoms, a high voltage generator for providing a high voltage to draw out and accelerate the first and the second particle-beams, and a lens group having an optical lens and an objective for focusing the first and the second particle-beams on the substrate to deposit the multi-element compound nanostructure in the chamber.

The foregoing and other features and advantages of the present invention will be more clearly understood through the following descriptions with reference to the drawings, wherein:

### BRIEF DESCRIPTION OF THE DRAWINGS

FIG. 1 is a diagram schematically illustrating a method for fabricating a multi-element compound nanostructure according to the preferred embodiment of the present invention;

FIG. 2 is a diagram schematically illustrating an apparatus for fabricating a multi-element compound nanostructure according to the preferred embodiment of the present invention; and

FIG. 3 is a diagram schematically illustrating a zero dimensional nanostructure, a one dimensional nanostructure, a two dimensional nanostructure and a three dimensional nanostructure, which are fabricated via the method and apparatus according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

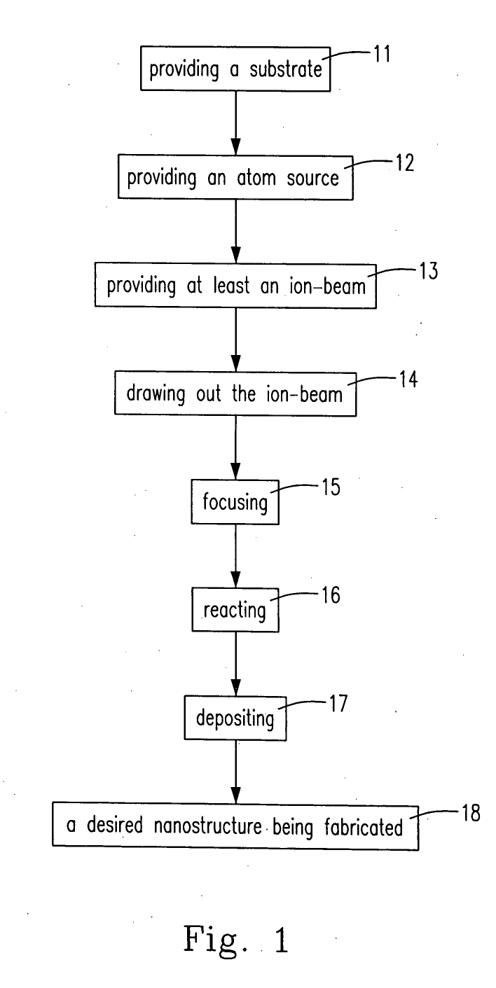

Please refer to FIG. 1, which is a diagram schematically illustrating a method for fabricating a multi-element compound nanostructure according to the preferred embodiment of the present invention. First, a substrate is provided in a chamber as shown in the step 11. The chamber is in vacuum and helpful to form a multi-element compound nanostructure which performs an excellent property therein. An atom source is also provided in the chamber as shown in the step 12, so that the chamber is filled with plural particles of the provided atom source. In a preferred embodiment, the atom source is a vaporized atom source. Then, at least a metal ion source is provided for respectively generating at least a metal ion-beam therefrom by means of a provided high voltage as shown in the step 13. The metal ion-beams are drawn out and accelerated via the high voltage and then pass through a lens group for being focused on the substrate as shown in the steps 14 and 15, respectively. Since the respective beam diameters of the focused metal ion-beams are able to be reduced to several tens of nanometers or even to a smaller scale, hence the desired multi-element compound nanostructure which is formed by the reaction of the focused metal ion-beams and the atoms in the chamber is able to be precisely deposited on the substrate as shown in the steps 17 and 18, respectively. In the preferred embodiment, the lens group for focusing the metal ion-beams is an electromagnetic lens group which includes a combination of an optical lens and an objective.

Moreover, in order to improve the growth of the multi-element compound nanostructure, the substrate is heated via a provided heater to a growth temperature of the desired multi-element compound nanostructure. Besides, the substrate is further scanned via a provided electron-beam for precisely identifying the growth position of the multi-element compound nanostructure thereon. Alternatively, the substrate is patterned via the electron-beam, so that the desired multi-element compound nanostructure is formed corresponding thereto.

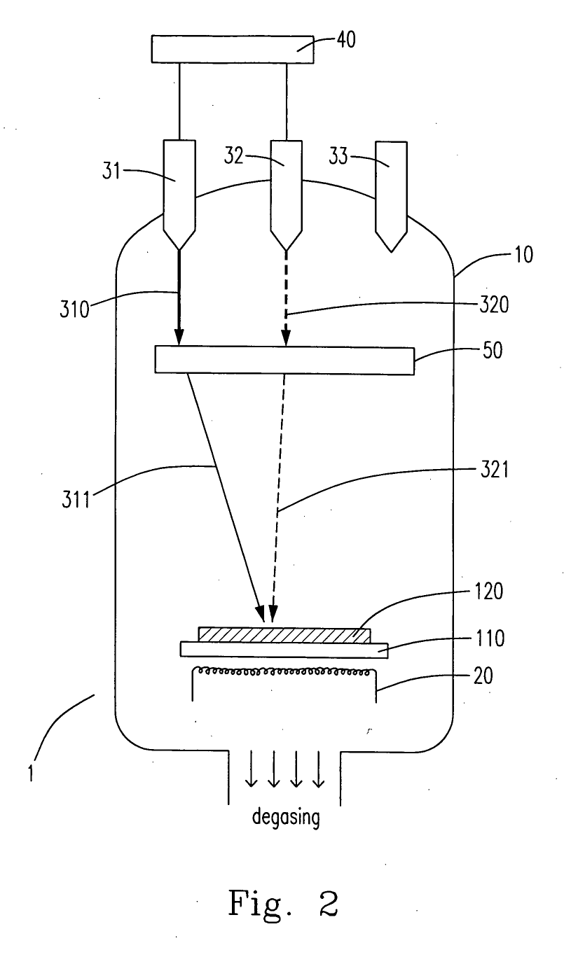

Please refer to FIG. 2, which is a diagram schematically illustrating an apparatus for fabricating a multi-element compound nanostructure according to the preferred embodiment of the present invention. In the preferred embodiment the apparatus for fabricating the multi-element compound nanostructure 1 typically includes a chamber 10, a heater 20, metal ion-beam sources of a first metal ion-beam source 31 and a second metal ion-beam source 32, an atom source 33, a high voltage device 40 and a lens group 50. Moreover, a base 110 is configured in the chamber 10 for holding the substrate therein, and the lens group 50 relates to an electromagnetic lens group which includes a combination of an optical lens and an objective.

A substrate 120 on which the multi-element compound nanostructure is formed and deposited is disposed on the base 110. The chamber 10 is degassed by an air-extracting apparatus or a vacuum pump (not shown) so as to make the chamber 10 to be in vacuum. The substrate 120 is heated by the heater 20 to the growth temperature of the multi-element compound nanostructure, so as to facilitate the growth of the multi-element compound nanostructure thereon.

The atom source 33 is a vaporized atom source which is provided for filling the chamber with the vaporized atoms. The high voltage device 40 provides a high voltage for drawing out and accelerating the first metal ion-beam 310 and the second metal ion-beam 320. The first metal ion-beam 310 and the second metal ion-beam 320 are accelerated to pass through the lens group 50, whereby a focused first metal ion-beam 311 and a focused second metal ion-beam 321 are formed. The focused first metal ion-beam 311 and the focused second metal ion-beam 321 are focused on the substrate 120 and react with the atoms in the chamber 10, so as to form the multi-element compound nanostructure thereon. That is to say, the multi-element compound nanostructure deposited on the substrate 120 is composed of the first metal, the second metal and the atom.

Furthermore, the substrate 120 is able to be scanned via a provided electron-beam so as to precisely identify a growth position of the multi-element compound nanostructure thereon. Alternatively, the substrate is patterned via the electron-beam, and hence the desired multi-element compound nanostructure is formed corresponding thereto.

It should be noted that the amount and the sorts of the metal ion sources for fabricating the multi-element compound nanostructure are selectable and depend on an actual application. For example, if an aluminum gallium nitride, i.e. AlGaN, nanostructure is to be grown and deposited on a substrate, a speedily vaporized atom source of N₂/NH₃ is selected to perform as the atom source 33 for providing the essential component of nitrogen for the desired AlGaN nanostructure. The first metal ion source 31 may be a gallium ion source, and the second metal ion source 32 may be an aluminum ion source. The gallium ion source as well as the aluminum ion source is liquid or vaporized. A gallium ion-beam and an aluminum ion-beam are respectively drawn out from the gallium ion source and the aluminum ion source via a high voltage provided by the high voltage device 40 and accelerated thereby to pass through the lens group 50. The gallium ion-beam and the aluminum ion-beam are focused accordingly, whose beam diameters are condensed in a range of several tens of nanometers or less, on the substrate 120 and react with the nitrogen atoms provided by the speedily vaporized atom source of N₂/NH₃, so as to form the AlGaN nanostructure deposited thereon.

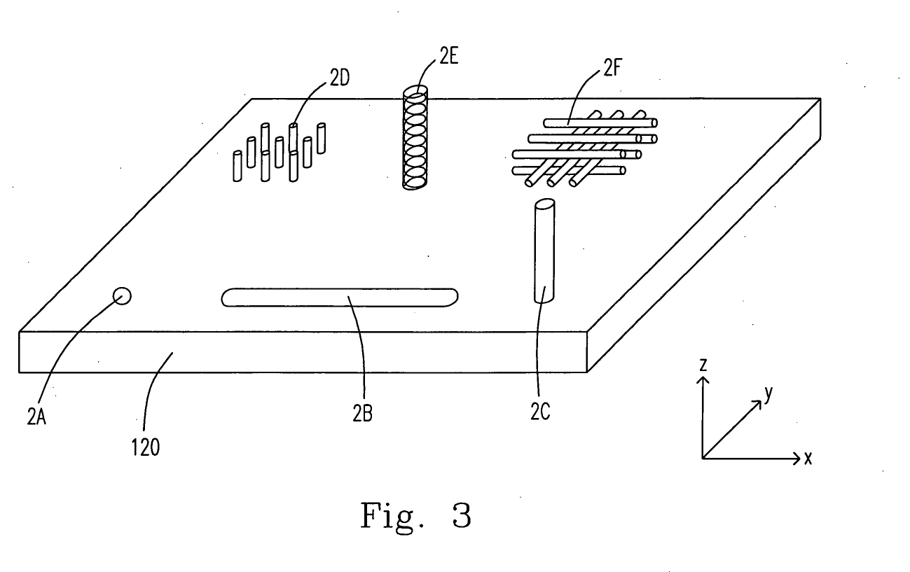

The multi-element compound nanostructure is formed from a reaction of the first and second metal ion-beams with the provided atoms, which merely occurs at the position on which the first and the second metal ion-beams are condensed. Since the first and the second metal ion-beams both have a condensed beam diameter in a range of several tens of nanometers, hence the first and the second metal ion-beams are precisely controllable via a conventional scanning technique, e.g. the SEM (scanning electron microscope) technique, and the multi-element compound nanostructure with a desired configuration is easily fabricated thereby. For example, with reference to FIG. 3 which is a diagram showing a multiplicity of nanostructures that could be formed by the provided method and apparatus according to the present invention, a quantum dot 2A is able to be formed and deposited on the substrate via keeping the first and the second metal ion-beams being focused on a stationary position thereon. Moreover, a nano-wire 2B and a nano-column 2C are formed and deposited on the substrate via controlling the first metal ion-beam as well as the second metal ion-beam to both move along the x direction and the z direction, respectively. Furthermore, the metal ion-beams are controllable to move in the x, y and z directions so as to form a stereo multi-element compound nanostructure, such as an array of nano-columns 2D, a nano-spiral 2E and a three-dimensional nano-network 2F.

Based on the above, the present invention provides a novel method and apparatus for efficiently fabricating a zero-dimensional, a one-dimensional, a two-dimensional and a three-dimensional multi-element compound nanostructure. In comparison with the conventional ones, a desired multi-element compound nanostructure is able to be easily and precisely fabricated by means of the present invention without needing additional processes. Furthermore, the use of the ion-beams as well as the electron beams also meets the demands for improving the present nano-technology and has a great potentiality in being combined therewith. Therefore, the present invention not only has a novelty and a progressiveness, but also has an industry utility.

While the invention has been described in terms of what is presently considered to be the most practical and preferred embodiment, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

1-18. (canceled)

19. An apparatus for fabricating a multi-element compound nanostructure, comprising:
a chamber in vacuum having a base for holding a substrate therein;
a heating device in said chamber for heating said substrate;
plural particle sources having at least a first and a second particle sources for providing a first and a second particle-beams respectively;
an atom source for providing said chamber with plural atoms;
a high voltage generator for providing a high voltage to draw out and accelerate said first and said second particle-beams; and
a lens group having an optical lens and an objective for focusing said first and said second particle-beams on a position of said substrate to deposit said multi-element compound nanostructure in said chamber.
